(19) United States
(12) Patent Application Publication
(10) Pub. No.: US 2026/0271240 A1
(43) Pub. Date: Sep. 10, 2026

(54) COOLING PLATE DEVICE, HEAT DISSIPATION SYSTEM, AND SERVER

(71) Applicants: SQ TECHNOLOGY (SHANGHAI) CORPORATION, Shanghai (CN); INVENTEC CORPORATION, Taipei (TW)

(72) Inventors: Zhao Geng, Shanghai (CN); Hong-Chou Lin, Taipei (TW); Yu-Fan Chen, Taipei (TW)

(21) Appl. No.: 19/207,356

(22) Filed: May 14, 2025

(30) Foreign Application Priority Data
Mar. 7, 2025 (CN) 202510273732.6

(51) Int. Cl. H05K 7/20

(52) U.S. Cl. CPC H05K 7/20772; H05K 7/20927

(57) ABSTRACT

A cooling plate device, a heat dissipation system, and a server are provided. The cooling plate device comprises: a transmission assembly comprising a first water inlet pipe, a first water outlet pipe, a first connecting plate, and a second connecting plate, the first water inlet pipe comprising a first nozzle and a second nozzle, the first nozzle being connected to the first connecting plate, the first water outlet pipe comprising a third nozzle, and the third nozzle being connected to the second connecting plate; a memory cooling plate, one end of the memory cooling plate being connected to the first connecting plate, another end of the memory cooling plate being connected to the second connecting plate, the first water inlet pipe, the first connecting plate, the memory cooling plate, the second connecting plate, and the first water outlet pipe being sequentially connected to form a liquid cooling channel.

### CROSS-REFERENCE TO RELATED APPLICATIONS

This application claims priority of Chinese Patent Application No. 2025102737326, filed on Mar. 7, 2025, entitled “COOLING PLATE DEVICE, HEAT DISSIPATION SYSTEM, AND SERVER”, the entire content of which is incorporated herein by reference in its entirety.

### TECHNICAL FIELD

The present disclosure relates to the technical field of computing devices, and in particular to a cooling plate device, a heat dissipation system, and a server.

### BACKGROUND

With the upgrading of server core computing chips, the power consumption of the server chips is increasing, and the heat generated by the server chips is also increasing accordingly.

The conventional way of using air cooling for heat dissipation can no longer meet the heat dissipation requirements of today's server chips, and air cooling needs to occupy a large amount of space in the server, which cannot satisfy the high-integration design requirements of the server. In addition, when a fan is used as a main heat dissipation component of the server, its power consumption accounts for an increasing proportion of the total power consumption of the server, and the overall PUE (a ratio of all energy consumed by a data center to the energy consumed by an IT load) of the server is increased reversely, which has the defects of poor heat dissipation effect, large space occupation and low energy efficiency.

### SUMMARY

Accordingly, it is necessary to provide a cooling plate device, a heat dissipation system, and a server to address the problems of poor heat dissipation effect, large space occupation and low energy efficiency in the heat dissipation of the server.

A cooling plate device includes:
a transmission assembly including a first water inlet pipe, a first water outlet pipe, a first connecting plate, and a second connecting plate, the first water inlet pipe including a first nozzle and a second nozzle, the first nozzle being connected to the first connecting plate, the first water outlet pipe including a third nozzle and a fourth nozzle, and the third nozzle being connected to the second connecting plate;
a memory cooling plate, one end of the memory cooling plate being connected to the first connecting plate, another end of the memory cooling plate being connected to the second connecting plate, the first water inlet pipe, the first connecting plate, the memory cooling plate, the second connecting plate, and the first water outlet pipe being sequentially connected to form a liquid cooling channel, and a liquid cooling medium being provided in the liquid cooling channel; and
a voltage regulator cooling plate provided on at least one of the first connecting plate and the second connecting plate.

A heat dissipation system includes a second water inlet pipe, a second water outlet pipe, a first water separator, a second water separator, and at least two cooling plate devices according to any one of the above embodiments. The first water separator is provided with a fifth water inlet and at least two fifth water outlets, the fifth water inlet is in communication with the at least two fifth water outlets, the second water separator is provided with a sixth water outlet and at least two sixth water inlets, the sixth water outlet is in communication with the at least two sixth water inlet, the second water inlet pipe is connected to the fifth water inlet, the second nozzles of at least two first water inlet pipes are connected to the at least two fifth water outlets in a one-to-one correspondence, the fourth nozzles of at least two first water outlet pipes are connected the at least two sixth water inlets in a one-to-one correspondence, and the second water outlet pipe is connected to the sixth water outlet.

A server includes a cabinet body, a motherboard, a processor, a memory and the heat dissipation system described in the above embodiment. The cabinet body is provided with an accommodating cavity, the motherboard is provided in the accommodating cavity, and the processor and the memory are mounted on the motherboard. The first connecting plate is provided with a first guide hole, the second connecting plate is provided with a second guide hole, the motherboard is provided with a first guide column and a second guide column, the cooling plate device is mounted on the motherboard, the first guide column is inserted into the first guide hole, and the second guide column is inserted into the second guide hole. The memory is provided in a memory mounting space of the cooling plate device, both ends of the memory are respectively engaged in a first mounting groove and a second mounting groove of the cooling plate device, respectively, and both side surfaces of the memory abut against the memory cooling plate. The cooling plate device includes a processor cooling plate abutting against the processor. The server further includes a voltage regulator provided on the motherboard, and the voltage regulator abuts against the voltage regulator cooling plate.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is a front view of a cooling plate device according to an embodiment of the present disclosure.

FIG. 2 is an exploded view of the cooling plate device of FIG. 1.

FIG. 3 is a cross-sectional view taken along a line A-A of FIG. 1.

FIG. 4 is an enlarged view of a circled portion of FIG. 3.

FIG. 5 is a front view of a heat dissipation system according to an embodiment of the present disclosure.

FIG. 6 is a perspective view of the heat dissipation system of FIG. 5.

FIG. 7 is a perspective view of a server according to an embodiment of the present disclosure.

### DESCRIPTIONS OF REFERENCE SIGNS

100, transmission assembly; 110, first water inlet pipe; 111, first nozzle; 112, second nozzle; 120, first water outlet pipe; 121, third nozzle; 122, fourth nozzle; 130, connecting water pipe; 131, fifth nozzle; 132, sixth nozzle; 140, first connecting plate; 141, first water inlet; 142, first water outlet; 140A, first guide hole; 143, first guide cover plate; 143A, first mounting groove; 150, second connecting plate; 151, second water outlet; 152, second water inlet; 150A, second guide hole; 153, second guide cover plate; 153A, second mounting groove; 161, first liquid receiving tray; 162, second liquid receiving tray; 163, third liquid receiving tray; 164, fourth liquid receiving tray;
200, processor cooling plate; 210, third water inlet; 220, third water outlet;
300, memory cooling plate; 300A, memory mounting space; 310, fourth water inlet; 320, fourth water outlet; 330, heat conducting gasket; 340, film;
400, voltage regulator cooling plate;
500, mounting handle; 510, first connecting portion; 511, first fastener; 520, second connecting portion; 521, second fastener; 530, third connecting portion; 531, third fastener;
1, heat dissipation system; 10, cooling plate device; 11, second water inlet pipe; 12, second water outlet pipe; 13, first water separator; 13A, fifth water inlet; 13B, fifth water outlet; 14, second water separator; 14A, sixth water outlet; 14B, sixth water inlet; 15, first quick connector; 16, second quick connector;
2, cabinet body; 2A, accommodation cavity; 3, motherboard; 31, first guide column; 32, second guide column; 33, voltage regulator.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

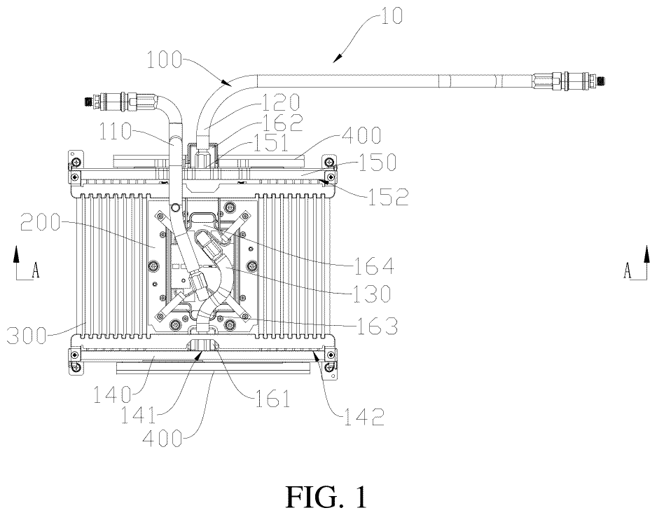

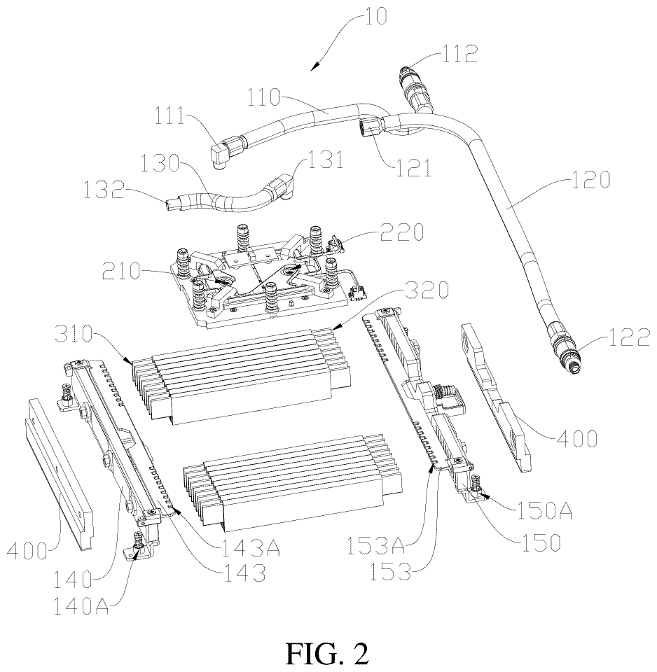

Referring to FIG. 1 and FIG. 2, a front view of a cooling plate device 10 and an exploded view of the cooling plate device 10 according to an embodiment of the present disclosure are shown. The cooling plate device 10 includes a transmission assembly 100, a memory cooling plate 300, and a voltage regulator cooling plate 400. The transmission assembly 100 includes a first water inlet pipe 110, a first water outlet pipe 120, a first connecting plate 140, and a second connecting plate 150. The first water inlet pipe 110 includes a first nozzle 111 and a second nozzle 112, and the first nozzle 111 is connected to the first connecting plate 140. The first water outlet pipe 120 includes a third nozzle 121 and a fourth nozzle 122, and the third nozzle 121 is connected to the second connecting plate 150.

One end of the memory cooling plate 300 is connected to the first connecting plate 140, and the other end of the memory cooling plate 300 is connected to the second connecting plate 150. The first water inlet pipe 110, the first connecting plate 140, the memory cooling plate 300, the second connecting plate 150 and the first water outlet pipe 120 are sequentially connected to form a liquid cooling channel, and a liquid cooling medium is provided in the liquid cooling channel.

In an optional embodiment, the liquid cooling medium may be one of a water-based medium, a propylene glycol and ethylene glycol solution, an oil, and a fluorinated liquid.

The voltage regulator cooling plate 400 is provided on the first connecting plate 140 and/or the second connecting plate 150.

According to the cooling plate device 10 described in the embodiment of the present disclosure, the first water inlet pipe 110, the first connecting plate 140, the memory cooling plate 300, the second connecting plate 150, and the first water outlet pipe 120 are sequentially connected to form the liquid cooling channel, the memory cooling plate 300 of the cooling plate device 10 is configured to abut against a memory of a server. The liquid cooling medium is input into the liquid cooling channel, and the liquid cooling medium circulates in the memory cooling plate 300, so that the heat of the memory is transferred to the liquid cooling medium through the memory cooling plate 300, thereby achieving the purpose of heat dissipation. Moreover, the voltage regulator cooling plate 400 may be provided on a side of the first connecting plate 140 and/or a side of the second connecting plate according to the position of a voltage regulator 33, so that the heat of the voltage regulator 33 is transferred to the liquid cooling medium through the voltage regulator cooling plate 400, thereby cooling the voltage regulator 33.

According to the cooling plate device 10 described in the embodiment of the present disclosure, the memory cooling plate 300 efficiently exchanges heat with the memory, and the voltage regulator cooling plate 400 efficiently exchanges heat with the voltage regulator 33, so that the heat dissipation efficiency and the system reliability of the server can be greatly improved. Furthermore, the memory cooling plate 300 is provided between the first connecting plate 140 and the second connecting plate 150, and the voltage regulator cooling plate 400 is provided on the side of the first connecting plate 140 and/or the side of the second connecting plate 150, so that the components are integrated into a whole, the layout is reasonable, and the overall occupied space is small. It is suitable for the assembly space requirements and heat dissipation requirements of general servers of 1U and above, and has the advantages of good heat dissipation effect, small occupied space and high energy efficiency.

In an optional embodiment, as shown in FIGS. 1 and 2, the cooling plate device 10 further includes a processor cooling plate 200. The transmission assembly 100 further includes a connecting water pipe 130. The first nozzle 111 is connected to the processor cooling plate 200. The connecting water pipe 130 includes a fifth nozzle 131 and a sixth nozzle 132, the fifth nozzle 131 is connected to the processor cooling plate 200, and the sixth nozzle 132 is connected to the first connecting plate 140, so that the processor cooling plate 200 and the connecting water pipe 130 are connected between the first water inlet pipe 110 and the first connecting plate 140 of the liquid cooling channel. By inserting the processor cooling plate 200 into the liquid cooling channel, the liquid cooling medium passes through the processor cooling plate 200, and the processor cooling plate 200 is configured to abut against a processor of the server, so that the heat of the processor is transferred to the liquid cooling medium through the processor cooling plate 200, thereby performing efficient heat exchange on the processor, and improving the heat dissipation efficiency and system reliability of the server.

In an exemplary embodiment, as shown in FIG. 1, the processor cooling plate 200 is provided between the first connecting plate 140 and the second connecting plate 150, and the memory cooling plate 300 is provided on both sides of the processor cooling plate 200 along a first direction. The first direction is an extending direction of the first connecting plate 140 or the second connecting plate 150.

In an optional embodiment, the processor cooling plate 200, the memory cooling plate 300, the voltage regulator cooling plate 400, the first connecting plate 140, and the second connecting plate 150 are all made of a metal with high thermal conductivity, such as copper or a copper-aluminum alloy, so as to improve the thermal conductivity of the cooling plate device 10, thereby improving the heat dissipation efficiency. In other embodiments, the processor cooling plate 200, the memory cooling plate 300, the voltage regulator cooling plate 400, the first connecting plate 140, and the second connecting plate 150 may also be made of aluminum to adapt to some lightweight requirements.

In some embodiments, as shown in FIG. 1 and FIG. 2, the first connecting plate 140 is provided with a first water inlet 141 and a first water outlet 142 that are in communication with each other. The second connecting plate 150 is provided with a second water outlet 151 and a second water inlet 152 that are in communication with each other. The sixth nozzle 132 is connected to the first water inlet 141, and the fourth nozzle 122 is connected to the second water outlet 151. The processor cooling plate 200 is provided with a third water inlet 210 and a third water outlet 220, the first nozzle 111 is connected to the third water inlet 210, and the fifth nozzle 131 is connected to the third water outlet 220. The memory cooling plate 300 is provided with a fourth water inlet 310 and a fourth water outlet 320. The fourth water inlet 310 is connected to the first water outlet 142 in a one-to-one correspondence. The fourth water outlet 320 is connected to the second water inlet 152 in a one-to-one correspondence. The third nozzle 121 of the first water outlet pipe 120 is connected to the second water outlet 151.

In this embodiment, the liquid cooling medium is input into the processor cooling plate 200 through the third water inlet 210, and then is input into the connecting water pipe 130 through the third water outlet 220. The first connecting plate 140 is provided with the first water inlet 141, so that the liquid cooling medium from the connecting water pipe 130 is input into the first connecting plate 140 through the first water inlet 141, and then is input into the memory cooling plate 300 through the first water outlet 142 and the fourth water inlet 310. After the memory cooling plate 300 exchanges heat with the memory, the liquid cooling medium is input into the second connecting plate 150 through the fourth water outlet 320 and the second water inlet 152, and then is input into the first water outlet pipe 120 through the second water outlet 151, thereby forming the complete liquid cooling channel, so that the cooling plate device 10 has efficient heat dissipation capability.

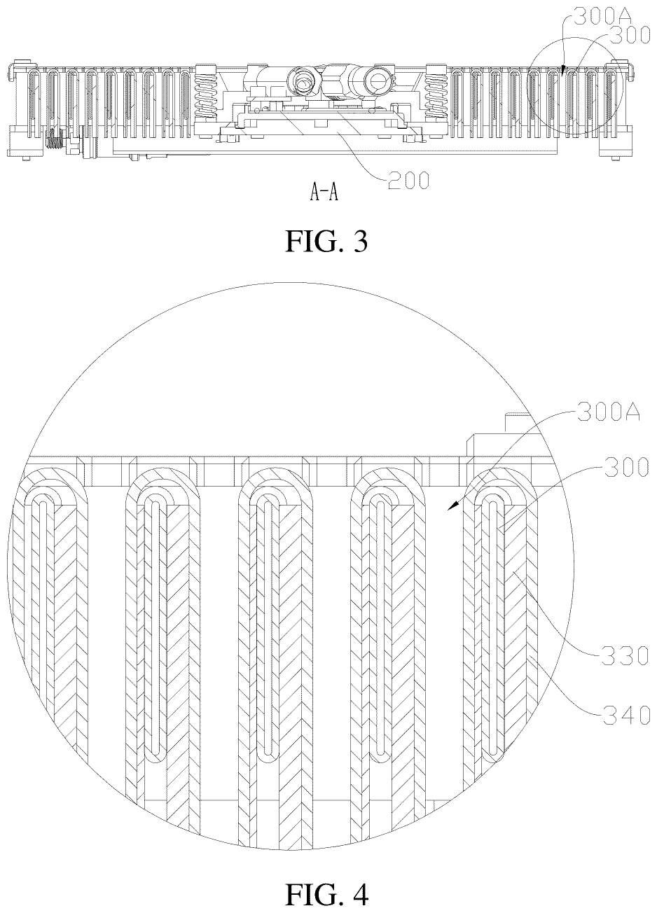

Referring to FIG. 3, a cross-sectional view of the memory cooling plate 300 of the cooling plate device 10 in an embodiment of the present disclosure is shown. In an optional embodiment, a plurality of memory cooling plates 300 are provided and are spaced apart along the first direction. A memory mounting space 300A is provided between adjacent two memory cooling plates 300. The first direction is the extending direction of the first connecting plate 140 or the second connecting plate 150. Since a plurality of memories are generally mounted in the server, and the plurality of memory cooling plates 300 are spaced apart, a plurality of memory mounting spaces 300A are respectively provided between a plurality of groups of adjacent two memory cooling plates 300. The memories can be mounted in the memory mounting spaces 300A in a one-to-one correspondence. Both sides of each memory abut against the memory cooling plates 300, so as to perform heat exchange on both sides of the memory, so that the memory cooling plate 300 can fully dissipate the heat of the memory and has an excellent heat dissipation effect.

In an exemplary embodiment, as shown in FIG. 1, the processor cooling plate 200 is provided between the first connecting plate 140 and the second connecting plate 150, and a plurality of memory cooling plates 300 of the same number are provided on both sides of the processor cooling plate 200, so that the processor cooling plate 200 and the memory cooling plate 300 form a symmetrical structure, thereby ensuring that the temperature difference of the liquid cooling mediums entering the processor cooling plate 200 and the memory cooling plate 300 is small and the heat dissipation performance is more balanced.

In an optional embodiment, as shown in FIG. 4, the memory cooling plate 300 is provided with a heat conducting gasket 330 and a film 340. The heat conducting gasket 330 is connected to at least one side surface of the memory cooling plate 300, and the film 340 wraps outer surfaces of the memory cooling plate 300 and the heat conducting gasket 330. Specifically, the heat conducting gasket 330 may be provided on one side or both sides of the memory cooling plate 300, so that the memory and the heat conducting gasket 330 are mounted in an interference fit. By providing the heat conducting gasket 330 on the side surface of the memory cooling plate 300, a good heat-conducting contact is achieved between the memory and the memory cooling plate 300, thereby ensuring the heat dissipation effect of the memory cooling plate 300. Furthermore, the outer surfaces of the memory cooling plate 300 and the heat conducting gasket 330 330 are wrapped with the film 340, so as to prevent the heat conducting gasket 330 from scratching the memory and ensure the operation stability of the server.

In an optional embodiment, as shown in FIG. 1 and FIG. 2, the cooling plate device 10 further includes a first guide cover plate 143 and a second guide cover plate 153. The first guide cover plate 143 is movably mounted on the first connecting plate 140 and is provided with a plurality of first mounting grooves 143A. The second guide cover plate 153 is movably mounted on the second connecting plate 150 and is provided with a plurality of second mounting grooves 153A. The plurality of first mounting grooves 143A and the plurality of second mounting grooves 153A are opposite to each other in a one-to-one correspondence, and the plurality of first mounting grooves 143A and the plurality of second mounting grooves 153A are provided corresponding to the memory mounting spaces 300A. By providing the first guide cover plate 143 on the first connecting plate 140 and the second guide cover plate 153 on the second connecting plate 150, the first mounting grooves 143A of the first guide cover plate 143 and the second mounting grooves 153A of the second guide cover plate 153 are provided corresponding to the memory mounting spaces 300A, so that the memory can be mounted along guide openings of the first mounting groove 143A and the second mounting groove 153A during mounting, the mounting position of the memory is more accurate, and the memory is prevented from being extruded and damaged due to incorrect position during the mounting process, the memory is more convenient to being mounted, and the convenience in use is improved.

In an optional embodiment, as shown in FIG. 2, the first guide cover plate 143 is hinged above the first connecting plate 140, and the first guide cover plate 143 is provided with a fourth fastener for fixing the first guide cover plate 143 above the first connecting plate 140. The second guide cover plate 153 is hinged above the second connecting plate 150, and the second guide cover plate 153 is provided with a fifth fastener for fixing the second guide cover plate 153 above the second connecting plate 150. Specifically, the fourth fastener and the fifth fastener are both screws or bolts. When the memory is mounted in the cooling plate device 10, the first guide cover plate 143 is fixed to the first connecting plate 140 through the fourth fastener, and the second guide cover plate 153 is fixed to the second connecting plate 150 through the fifth fastener. At this time, the memory is positioned in the first mounting groove 143A and the second mounting groove 153A. When the memory needs to be disassembled, the fourth fastener and the fifth fastener are disassembled, and then the first guide cover plate 143 and the second guide cover plate 153 are rotated to release the limit on the memory, and then the memory can be disassembled using a tool.

In an optional embodiment, as shown in FIG. 1, the transmission assembly 100 further includes a first liquid receiving tray 161, a second liquid receiving tray 162, a third liquid receiving tray 163, and a fourth liquid receiving tray 164. The first liquid receiving tray 161 is connected to the first connecting plate 140 and is provided at a bottom portion of the sixth nozzle 132. The second liquid receiving tray 162 is connected to the second connecting plate 150 and is provided at a bottom portion of the third nozzle 121. The third liquid receiving tray 163 is provided at a bottom portion of the first nozzle 111. The fourth liquid receiving tray 164 is provided at a bottom portion of the fifth nozzle 131. The first liquid receiving tray 161 and the fourth liquid receiving tray 164 are respectively provided at the sixth nozzle 132 and the fifth nozzle 131, the second liquid receiving tray 162 is provided at the third nozzle 121, and the third liquid receiving tray 163 is provided at the first nozzle 111, so that each joint of the cooling plate device 10 is provided with the liquid receiving tray. When liquid leaks at the joint, the liquid receiving tray can receive the leaked liquid, thereby reducing the risk of damage to the device when liquid leakage occurs and improving the stability of operation.

In an optional embodiment, the first nozzle 111, the third nozzle 121, the fifth nozzle 131, and the sixth nozzle 132 are each provided with a liquid leakage monitoring member. Specifically, the liquid leakage monitoring member is a liquid leakage monitoring line. The liquid leakage monitoring line is provided at each joint of the cooling plate device 10, and the liquid leakage monitoring line is connected to a control module of the server to transmit a detected liquid leakage signal to the control module, so that the liquid leakage of the cooling plate device 10 can be detected in time, thereby reducing the risk of damaging the device due to the liquid leakage and improving the stability of operation.

In other embodiments, the liquid leakage monitoring member is a liquid leakage monitoring patch. The liquid leakage monitoring patch is provided at each joint of the cooling plate device 10, the liquid leakage monitoring patch can be checked regularly to detect whether there is liquid leakage in time, thereby reducing the risk of damaging the device due to the liquid leakage and improving the stability of operation.

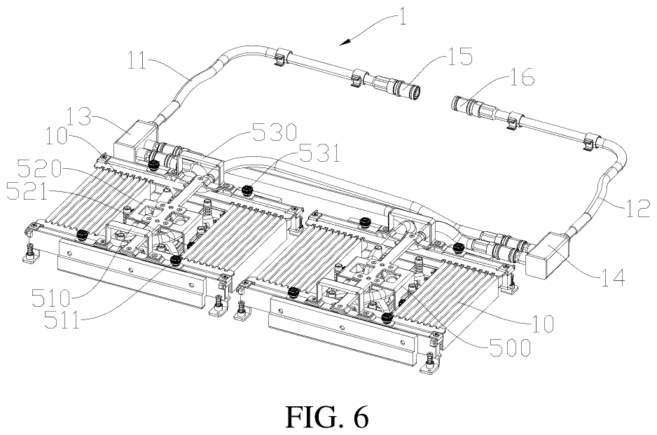

In an optional embodiment, as shown in FIG. 6, the cooling plate device 10 further includes a mounting handle 500, which includes a first connecting portion 510, a second connecting portion 520, and a third connecting portion 530. The first connecting portion 510 is detachably connected to the first connecting plate 140 through a first fastener 511. The second connecting portion 520 is detachably connected to the processor cooling plate 200 through a second fastener 521. The third connecting portion 530 is detachably connected to the second connecting plate 150 through a third fastener 531. Specifically, the first fastener 511, the second fastener 521, and the third fastener 531 are screws or bolts. In this embodiment, the first water inlet pipe 110, the first water outlet pipe 120, and the connecting water pipe 130 are flexible hoses. The flexible hoses are easy to manufacture, and the connection between the flexible hose and the processor cooling plate 200 and the connection between the flexible hose and the memory cooling plate 300 are not easily damaged. When mounting the cooling plate device 10, a relative position between the processor cooling plate 200 and the memory cooling plate 300 is difficult to fix due to the flexible hose connecting the two. Therefore, it is not easy to position them during mounting, and it needs many people to operate, and it is easy to damage important parts on the motherboard. In this embodiment, the mounting handle 500 is provided to connect the first connecting plate 140, the second connecting plate 150, and the processor cooling plate 200, so that all parts of the cooling plate device 10 are connected into a whole. When the mounting is completed, the mounting handle 500 can be removed to conveniently complete the mounting of the cooling plate device 10. Moreover, the mounting handle 500 can be used repeatedly during subsequent disassembly and assembly, and has the advantages of simple manufacture, convenient operation and low cost.

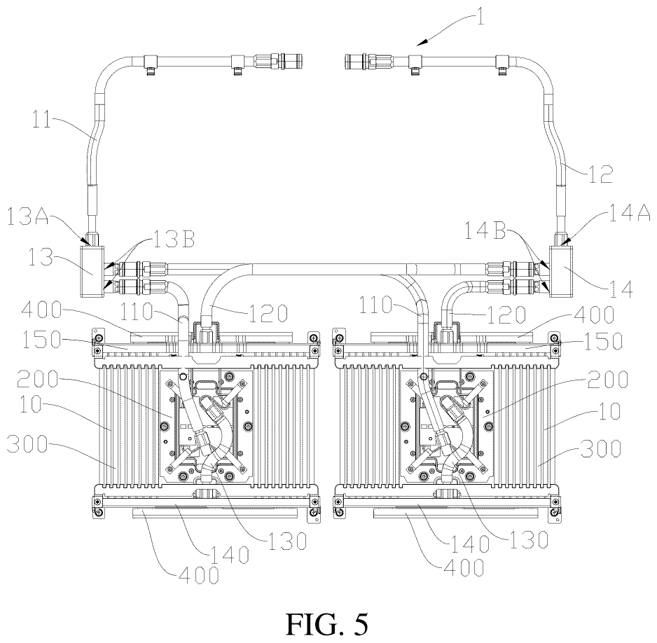

According to another aspect, the embodiment of the present disclosure further provides a heat dissipation system 1. As shown in FIGS. 5 and 6, the heat dissipation system 1 includes a second water inlet pipe 11, a second water outlet pipe 12, a first water separator 13, a second water separator 14, and at least two cooling plate devices 10 described in the above embodiments. The first water separator 13 is provided with a fifth water inlet 13A and at least two fifth water outlets 13B, and the fifth water inlet 13A is in communication with the at least two fifth water outlets 13B. The second water separator 14 is provided with a sixth water outlet 14A and at least two sixth water inlets 14B, and the sixth water outlet 14A is in communication with the at least two sixth water inlets 14B. The second water inlet pipe 11 is connected to the fifth water inlet 13A, the second nozzles 112 of at least two first water inlet pipes 110 are connected to the at least two fifth water outlets 13B in a one-to-one correspondence. The fourth nozzles 122 of at least two first water outlet pipes 120 are connected to the at least two sixth water inlets 14B in a one-to-one correspondence. The second water outlet pipe 12 is connected to the sixth water outlet 14A.

According to the heat dissipation system 1 described in the embodiment of the present disclosure, the first water separator 13 and the second water separator 14 are provided, so that more than two cooling plate devices 10 are connected in parallel to the second water inlet pipe 11 through the first water separator 13 when being mounted, thereby ensuring that the temperature difference of the liquid cooling medium entering each cooling plate device 10 is small, so that the heat dissipation performance of each cooling plate device 10 is more balanced, and has the advantage of high stability.

According to the heat dissipation system 1 described in the embodiment of the present disclosure, the cooling plate device 10 performs efficient heat exchange with the processor through the processor cooling plate 200, performs efficient heat exchange with the memory through the memory cooling plate 300, and performs efficient heat exchange with the voltage regulator 33 through the voltage regulator cooling plate 400, so that the heat dissipation efficiency and the system reliability of the server can be greatly improved. Furthermore, the memory cooling plate 300 is provided between the first connecting plate 140 and the second connecting plate 150, and the voltage regulator cooling plate 400 is provided on the side of the first connecting plate 140 and/or the side of the second connecting plate 150, so that the components are integrated into a whole, the layout is reasonable, and the overall occupied space is small. It is suitable for the assembly space requirements and heat dissipation requirements of general servers of 1U and above, and has the advantages of good heat dissipation effect, small occupied space and high energy efficiency.

In an optional embodiment, as shown in FIG. 5 and FIG. 6, the heat dissipation system 1 further includes a first quick connector 15 and a second quick connector 16. The second water inlet pipe 11 is connected to the first quick connector 15, and the second water outlet pipe 12 is connected to the second quick connector 16. The first quick connector 15 is provided on the second water inlet pipe 11, and the second quick connector 16 is provided on the second water outlet pipe 12, so that the heat dissipation system 1 can be more conveniently connected to a liquid cooling cabinet.

In an exemplary embodiment, the first quick connector 15 is a hand-insertion quick connector or a blind-insertion quick connector. The second quick connector 16 is a hand-insertion quick connector or a blind-insertion quick connector.

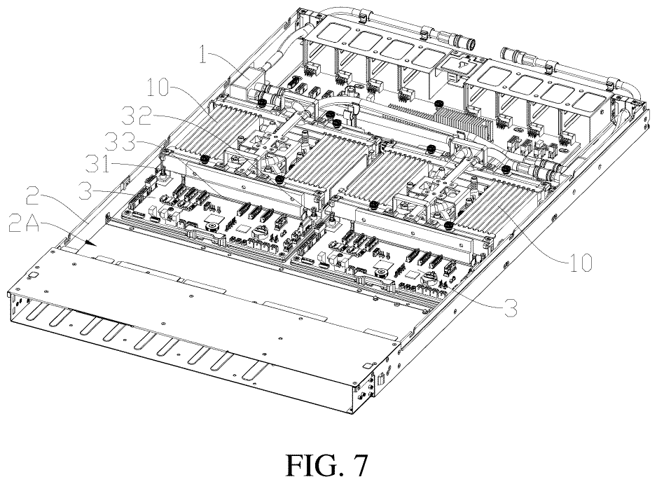

According to yet another aspect, the embodiment of the present disclosure further provides a server. As shown in FIG. 7, the server includes a cabinet body 2, a motherboard 3, a voltage regulator 33, a processor, a memory, and the heat dissipation system 1 described in any of the above embodiments. The cabinet body 2 is provided with an accommodating cavity 2A, the motherboard 3 is provided in the accommodating cavity 2A, and the processor and the memory are mounted on the motherboard 3. The first connecting plate 140 is provided with a first guide hole 140A. The second connecting plate 150 is provided with a second guide hole 150A. The motherboard 3 is provided with a first guide column 31 and a second guide column 32. The cooling plate device 10 is mounted on the motherboard 3, the first guide column 31 is inserted in to the first guide hole 140A, and the second guide column 32 is inserted into the second guide hole 150A. The memory is provided in the memory mounting space 300A of the cooling plate device 10, and both ends of the memory are engaged in the first mounting groove 143A and the second mounting groove 153A of the cooling plate device 10, respectively, and both side surfaces of the memory abut against the memory cooling plate 300. The processor cooling plate 200 abuts against the processor. The voltage regulator 33 is provided on motherboard 3, and the voltage regulator 33 abuts against the voltage regulator cooling plate 400.

According to the server described in the embodiment of the present disclosure, the heat dissipation system 1 is mounted on the motherboard 3, the cooling plate device 10 of the heat dissipation system 1 performs efficient heat exchange with the processor through the processor cooling plate 200, performs efficient heat exchange with the memory through the memory cooling plate 300, and performs efficient heat exchange with the voltage regulator 33 through the voltage regulator cooling plate 400, so that the heat dissipation efficiency and the system reliability of the server can be greatly improved. Furthermore, the memory cooling plate 300 is provided between the first connecting plate 140 and the second connecting plate 150, and the voltage regulator cooling plate 400 is provided on the side of the first connecting plate 140 and/or the side of the second connecting plate 150, so that the components are integrated into a whole, the layout is reasonable, and the overall occupied space is small. It is suitable for the assembly space requirements and heat dissipation requirements of general servers of 1U and above, and has the advantages of good heat dissipation effect, small occupied space and high energy efficiency.

In an optional embodiment, the motherboard 3 is provided with the first guide column 31 and the second guide column 32, so that when the cooling plate device 10 is mounted, the first guide hole 140A of the first connecting plate 140 corresponds to the first guide column 31 and the second guide hole 150A of the second connecting plate 150 corresponds to the second guide column 32 for mounting. Therefore, the cooling plate device 10 can be conveniently positioned during mounting, and high positioning accuracy of the cooling plate device 10 is ensured, the heat dissipation effect is ensured, which has the advantages of convenience in mounting and good heat dissipation effect.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. A cooling plate device, comprising:
a transmission assembly comprising a first water inlet pipe, a first water outlet pipe, a first connecting plate, and a second connecting plate, the first water inlet pipe comprising a first nozzle and a second nozzle, the first nozzle being connected to the first connecting plate, the first water outlet pipe comprising a third nozzle and a fourth nozzle, and the third nozzle being connected to the second connecting plate;
a memory cooling plate, one end of the memory cooling plate being connected to the first connecting plate, another end of the memory cooling plate being connected to the second connecting plate, the first water inlet pipe, the first connecting plate, the memory cooling plate, the second connecting plate, and the first water outlet pipe being sequentially connected to form a liquid cooling channel, and a liquid cooling medium being provided in the liquid cooling channel; and
a voltage regulator cooling plate provided on at least one of the first connecting plate and the second connecting plate.

2. The cooling plate device according to claim 1, further comprising a processor cooling plate, wherein the transmission assembly further comprises a connecting water pipe, the first nozzle is connected to the processor cooling plate, the connecting water pipe comprises a fifth nozzle and a sixth nozzle, the fifth nozzle is connected to the processor cooling plate, the sixth nozzle is connected to the first connecting plate, so that the processor cooling plate and the connecting water pipe are connected between the first water inlet pipe and the first connecting plate of the liquid cooling channel.

3. The cooling plate device according to claim 1, wherein a plurality of memory cooling plates are provided and are spaced apart along a first direction, and a memory mounting space is provided between adjacent two memory cooling plates.

4. The cooling plate device according to claim 1, wherein the memory cooling plate is provided with a heat conducting gasket and a film, the heat conducting gasket is connected to at least one side surface of the memory cooling plate, and the film wraps outer surfaces of the memory cooling plate and the heat conducting gasket.

5. The cooling plate device according to claim 3, further comprises a first guide cover plate and a second guide cover plate, wherein the first guide cover plate is movably mounted on the first connecting plate and is provided with a plurality of first mounting grooves, the second guide cover plate is movably mounted on the second connecting plate and is provided with a plurality of second mounting grooves, the plurality of first mounting grooves and the plurality of second mounting grooves are opposite to each other in a one-to-one correspondence, and the plurality of first mounting grooves and the plurality of second mounting grooves are provided corresponding to a plurality of memory mounting spaces.

6. The cooling plate device according to claim 2, wherein the transmission assembly further comprises a first liquid receiving tray, a second liquid receiving tray, a third liquid receiving tray, and a fourth liquid receiving tray, the first liquid receiving tray is connected to the first connecting plate and is provided at a bottom portion of the sixth nozzle, the second liquid receiving tray is connected to the second connecting plate and is provided at a bottom portion of the third nozzle, the third liquid receiving tray is provided at a bottom portion of the first nozzle, and the fourth liquid receiving tray is provided at a bottom portion of the fifth nozzle.

7. The cooling plate device according to claim 2, wherein the first nozzle, the third nozzle, the fifth nozzle, and the sixth nozzle are each provided with a liquid leakage monitoring member.

8. The cooling plate device according to claim 2, further comprises a mounting handle, wherein the mounting handle comprises a first connecting portion, a second connecting portion, and a third connecting portion, the first connecting portion is detachably connected to the first connecting plate through a first fastener, the second connecting portion is detachably connected to the processor cooling plate through a second fastener, and the third connecting portion is detachably connected to the second connecting plate through a third fastener.

9. A heat dissipation system, comprising a second water inlet pipe, a second water outlet pipe, a first water separator, a second water separator, and at least two cooling plate devices according to claim 1, wherein the first water separator is provided with a fifth water inlet and at least two fifth water outlets, the fifth water inlet is in communication with the at least two fifth water outlets, the second water separator is provided with a sixth water outlet and at least two sixth water inlets, the sixth water outlet is in communication with the at least two sixth water inlet, the second water inlet pipe is connected to the fifth water inlet, the second nozzles of at least two first water inlet pipes are connected to the at least two fifth water outlets in a one-to-one correspondence, the fourth nozzles of at least two first water outlet pipes are connected the at least two sixth water inlets in a one-to-one correspondence, and the second water outlet pipe is connected to the sixth water outlet.

10. A server, comprising a cabinet body, a motherboard, a processor, a memory, and the heat dissipation system according to claim 9, wherein the cabinet body is provided with an accommodating cavity, the motherboard is provided in the accommodating cavity, and the processor and the memory are mounted on the motherboard;
wherein the first connecting plate is provided with a first guide hole, the second connecting plate is provided with a second guide hole, the motherboard is provided with a first guide column and a second guide column, the cooling plate device is mounted on the motherboard, the first guide column is inserted into the first guide hole, and the second guide column is inserted into the second guide hole;
wherein the memory is provided in a memory mounting space of the cooling plate device, both ends of the memory are respectively engaged in a first mounting groove and a second mounting groove of the cooling plate device, respectively, and both side surfaces of the memory abut against the memory cooling plate;
wherein the cooling plate device comprises a processor cooling plate abutting against the processor;
wherein the server further comprises a voltage regulator provided on the motherboard, and the voltage regulator abuts against the voltage regulator cooling plate.
